(19) United States
(12) Patent Application Publication
(10) Pub. No.: US 2025/0318016 A1
(43) Pub. Date: Oct. 9, 2025

(54) TEMPERATURE CONTROL AND DETECTION SYSTEM

(71) Applicant: KINSUS INTERCONNECT TECHNOLOGY CORP., Taoyuan City (TW)

(72) Inventors: Chien-Jung KUO, Taoyuan City (TW); Ying-Chang LI, Taoyuan City (TW)

(21) Appl. No.: 18/760,154

(22) Filed: Jul. 1, 2024

(30) Foreign Application Priority Data
Apr. 9, 2024 (TW) 113113407

(51) Int. Cl. H05B 1/02; G01R 31/52; H02H 7/20

(52) U.S. Cl. CPC H05B 1/02; H02H 7/20; G01R 31/52

(57) ABSTRACT

A temperature control and detection system is configured to detect an electrical status and a thermal status of a heating device, and includes a control apparatus, a trip detector, a phase loss detector, and a current detector. When detecting that the leakage circuit breaker trips out, the trip detector generates a first abnormal signal and sends the first abnormal signal to the control apparatus. When detecting that a three-phase voltage is unbalanced, the phase loss detector generates a second abnormal signal and sends the second abnormal signal to the control apparatus. When detecting that a continuous current surge or a current is continuously lower than a threshold, the current detector generates a third abnormal signal and sends the third abnormal signal to the control apparatus. When receiving the first abnormal signal, the second abnormal signal, or the third abnormal signal, the control apparatus terminates operation of the heater.

### CROSS-REFERENCE TO RELATED APPLICATION

This non-provisional application claims priority under 35 U.S.C. § 119(a) to patent application Ser. No. 11/311,3407 filed in Taiwan, R.O.C. on Apr. 9, 2024, the entire contents of which are hereby incorporated by reference.

### BACKGROUND

### Technical Field

The present invention relates to the field of factory affairs, and in particular, to a temperature control and detection system.

### Related Art

A current electronic product includes a chip, a circuit board, a panel, and the like, and is usually completed after a plurality of processes are performed. In these processes, a temperature is a very important monitoring parameter for a process device, to avoid subsequent product deformation and electrical failure caused by a temperature effect. Therefore, currently, each device currently has temperature monitoring devices such as a thermocouple and a heat detector, to monitor a temperature of an entire device or a product, and notify a control end of factory affairs when the temperature exceeds a threshold.

However, as a production cost of products increases, when a temperature is abnormal, the products have usually been produced, and these products may have to be scrapped, which greatly increases the overall production cost and time.

### SUMMARY

To resolve problems faced in the conventional technology, a temperature control and detection system is provided herein. The temperature control and detection system is electrically connected to a heating device, and is configured to detect an electrical status and a thermal status of the heating device. The heating device includes a leakage circuit breaker, an electromagnetic contactor, a solid state relay, and a heater. In some embodiments, the temperature control and detection system includes a control apparatus, a trip detector, a phase loss detector, and a current detector.

The control apparatus is electrically connected to the leakage circuit breaker, the electromagnetic contactor, the solid state relay, and the heater. The trip detector is electrically connected to the control apparatus and the leakage circuit breaker, and when detecting that the leakage circuit breaker trips out, generates a first abnormal signal and sends the first abnormal signal to the control apparatus, to terminate operation of the heater. The phase loss detector is electrically connected to the electromagnetic contactor, the solid state relay, and the control apparatus, and when detecting that a three-phase voltage is unbalanced, generates a second abnormal signal and sends the second abnormal signal to the control apparatus, to terminate the operation of the heater. The current detector is electrically connected to the solid state relay, the heater, and the control apparatus, and when detecting that a continuous current surge or a current is continuously lower than a threshold, generates a third abnormal signal and sends the third abnormal signal to the control apparatus, to terminate the operation of the heater.

In some embodiments, the control apparatus includes a programmable logic control apparatus.

In some embodiments, the temperature control and detection system further includes a warning unit, where when receiving the first abnormal signal, the second abnormal signal, or the third abnormal signal, the control apparatus sends an actuating signal to start the warning unit.

In some embodiments, the temperature control and detection system further includes a communication unit, where when the control apparatus receives the first abnormal signal, the second abnormal signal, or the third abnormal signal, the control apparatus transmits the first abnormal signal, the control apparatus transmits the first abnormal signal, the second abnormal signal, or the third abnormal signal through the communication unit.

In some embodiments, the temperature control and detection system further includes an overheating detector, connected to the heater and the control apparatus, and when detecting that a temperature of the heater is excessively high, generating a fourth abnormal signal and sending the fourth abnormal signal to the control apparatus to terminate the operation of the heater.

More specifically, in some embodiments, the temperature control and detection system further includes a warning unit, where when receiving the first abnormal signal, the second abnormal signal, the third abnormal signal, or the fourth abnormal signal, the control apparatus sends an actuating signal to start the warning unit.

More specifically, in some embodiments, the temperature control and detection system further includes a communication unit, where when the control apparatus receives the first abnormal signal, the second abnormal signal, the third abnormal signal, or the fourth abnormal signal, the control apparatus transmits the first abnormal signal, the second abnormal signal, the third abnormal signal, or the fourth abnormal signal through the communication unit.

Further, in some embodiments, the temperature control and detection system further includes a resistance detector, connected to the heater, and when detecting that a fuse of the heater blows out, generating a fifth abnormal signal and sending the fifth abnormal signal to the control apparatus to terminate the operation of the heater.

More specifically, in some embodiments, the temperature control and detection system further includes a warning unit, where when receiving the first abnormal signal, the second abnormal signal, the third abnormal signal, the fourth abnormal signal, or the fifth abnormal signal, the control apparatus sends an actuating signal to start the warning unit.

More specifically, in some embodiments, the temperature control and detection system further includes a communication unit, where when the control apparatus receives the first abnormal signal, the second abnormal signal, the third abnormal signal, the fourth abnormal signal, or the fifth abnormal signal, the control apparatus transmits the first abnormal signal, the second abnormal signal, the third abnormal signal, the fourth abnormal signal, or the fifth abnormal signal through the communication unit.

As described in the foregoing embodiments, through disposing of the trip detector, the phase loss detector, and the current detector, as well as a logic circuit design of the control apparatus, an early warning notification may be issued in advance when a voltage and a current of the device are abnormal, and the operation of the heater is interrupted, to avoid occurrence of temperature abnormalities during processes, thereby improving an overall yield and reducing a cost generated by scrapping products.

### BRIEF DESCRIPTION OF THE DRAWINGS

FIG. 1 is a block diagram of a first embodiment of a temperature control and detection system; and

FIG. 2 is a block diagram of a second embodiment of a temperature control and detection system.

### DETAILED DESCRIPTION

It should be understood that when an element is referred to as being “disposed” on another element, it may indicate that the element is directly on the other element, or there may also be an intermediate element, and the element is connected to another element through the intermediate element. On the contrary, when an element is referred to as being “directly disposed on another element” or “directly disposed on another element”, it may be understood that at this time, it is clearly defined that there is no intermediate element.

In addition, terms “first”, “second”, and “third” are only used to distinguish one element, component, region, section, or layer from another element, component, region, layer, or section, rather than indicating an inevitable sequence therebetween. In addition, relative terms such as “under” and “upper” may be used herein to describe a relationship between one element and another element. It should be understood that relative terms are intended to include differences in devices other than the devices at the orientation shown in the drawing. For example, if the device in one accompanying drawing is flipped, elements described as being on “lower” sides of other elements are to be oriented on “upper” sides of the other elements. This only represents a relative position relationship, not an absolute position relationship.

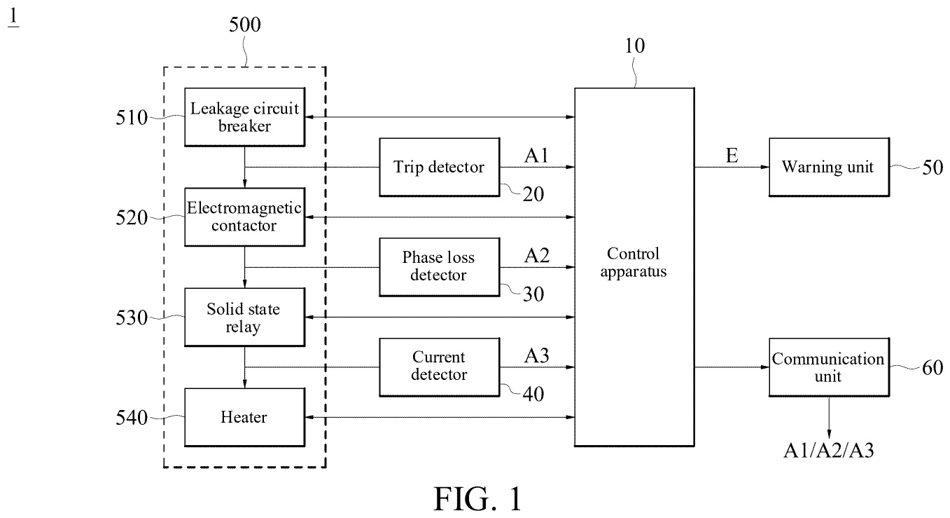

Given long-term research on site by the inventor and referring to FIG. 1, a heating device 500 generally includes a leakage circuit breaker 510, an electromagnetic contactor 520, a solid state relay 530, and a heater 540. A current sequentially flows through the leakage circuit breaker 510, the electromagnetic contactor 520, the solid state relay 530, and the heater 540. However, when leakage or short circuit occurs in the leakage circuit breaker 510, the three-phase current passing through the electromagnetic contactor 520 is unbalanced, the solid state relay 530 is abnormal, or the heater 540 is abnormal. For example, when not heated, a fuse blows out after a previous process is completed, it may cause abnormalities such as the heater 540 is unable to heat or overheat finally, and it is not easy to discover in an early stage of the process. This may result in being discovered after the process, or being terminated in the process, resulting in scrapping of a product.

Therefore, to resolve the problem, a temperature control and detection system 1 is provided herein. FIG. 1 is a block diagram of a first embodiment of a temperature control and detection system. As shown in FIG. 1, the temperature control and detection system 1 includes a control apparatus 10, a trip detector 20, a phase loss detector 30, and a current detector 40. The control apparatus 10 is electrically connected to a leakage circuit breaker 510, an electromagnetic contactor 520, a solid state relay 530, and a heater 540. The trip detector 20 is electrically connected to the control apparatus 10 and the leakage circuit breaker 510, and when detecting that the leakage circuit breaker 510 trips out, generates a first abnormal signal Al and sends the first abnormal signal A1 to the control apparatus 10.

The phase loss detector 30 is electrically connected to the electromagnetic contactor 520, the solid state relay 530, and the control apparatus 10, and when detecting that a three-phase voltage output by the solid state relay 530 is unbalanced, generates a second abnormal signal A2 and sends the second abnormal signal A2 to the control apparatus. The current detector 40 is electrically connected to the solid state relay 530, the heater 540, and the control apparatus 10, and when detecting that a continuous current surge or a current is continuously lower than a threshold, generates a third abnormal signal A3 and sends the third abnormal signal A3 to the control apparatus 10. In this case, the control apparatus 10 includes a programmable logic control apparatus, and the current detector 40 may include a current comparator. When receiving the first abnormal signal A1, the second abnormal signal A2, or the third abnormal signal A3, the control apparatus 10 terminates operation of the heater 540.

In this case, a logic of a circuit may be newly added to the control apparatus 10, to confirm the first abnormal signal A1, the second abnormal signal A2, or the third abnormal signal A3. For example, when a contact point of the leakage circuit breaker 510 or the heater 540 is connected, the trip detector 20 determines that the leakage circuit breaker 510 trips out, and determines that the leakage circuit breaker 510 trips out, and the first abnormal signal A1 is correct. When contact points of the heater 540, the electromagnetic contactor 520, and the solid state relay 530 are connected, it is determined that the three-phase voltage is unbalanced (phase loss), and then it is determined that the second abnormal signal A2 is consistent. When contact points of the heater 540 and the electromagnetic contactor 520 are connected, but a contact point of the solid state relay 530 is not connected, it is determined that a current is set too low, and then it is determined that the third abnormal signal A3 is consistent. However, the foregoing is merely an example, and is not intended to be a limit.

Further, referring to FIG. 1 again, in some embodiments, the temperature control and detection system 1 further includes a warning unit 50 and a communication unit 60. In some embodiments, when receiving the first abnormal signal A1, the second abnormal signal A2, or the third abnormal signal A3, the control apparatus 10 sends an actuating signal E to start the warning unit 50. The warning unit 50 may be a sound and light apparatus, to warn of an abnormal state of the leakage circuit breaker 510, the electromagnetic contactor 520, or the solid state relay 530. Further, when the control apparatus 10 receives the first abnormal signal A1, the second abnormal signal A2, or the third abnormal signal A3, the control apparatus 10 transmits the first abnormal signal A1, the second abnormal signal A2, or the third abnormal signal A3 through the communication unit 60. In this case, the communication unit 60 may further include functions of encryption and decryption, and transmit the first abnormal signal A1, the second abnormal signal A2, or the third abnormal signal A3 to a field device end or a monitoring end of factory affairs, to perform device replacement or repairing.

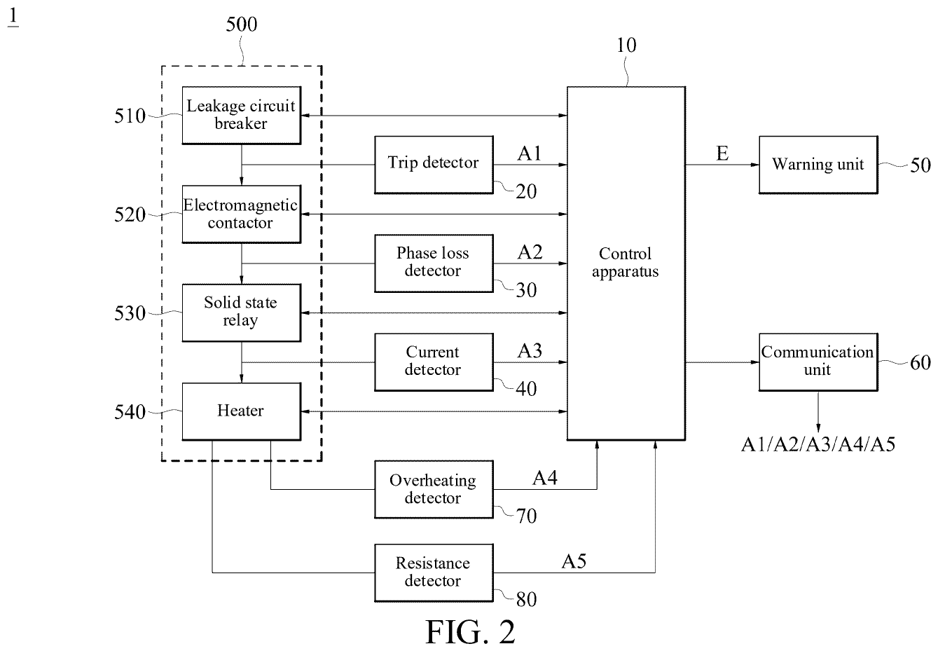

FIG. 2 is a block diagram of a second embodiment of a temperature control and detection system. As shown in FIG. 2, and referring to FIG. 1, in the second embodiment, the temperature control and detection system 1 further includes an overheating detector 70, connected to the heater 540 and the control apparatus 10, and when detecting that a temperature of the heater 540 is excessively high, the overheating detector 70 generates a fourth abnormal signal A4 and sends the fourth abnormal signal A4 to the control apparatus 10 to terminate the operation of the heater 540.

Further, the temperature control and detection system 1 further includes a resistance detector 80, connected to the heater 540, and when detecting that a fuse of the heater 540 blows out, generating a fifth abnormal signal A5 and sending the fifth abnormal signal A5 to the control apparatus 10 to terminate the operation of the heater 540. It should be noted herein that, both the overheating detector 70 and the resistance detector 80 independently monitor a status of the heater 540. When there is any problem, for example, if it is found that the fuse blows out during startup, the operation of the heater 540 is terminated, to avoid occurrence of problems such as interruption of a process or overheating, and achieve a preventive effect.

Further, a logic of a circuit may be further newly added to the control apparatus 10 to perform determining. For example, when a contact point of the heater 540 is connected, and a contact point of the resistance detector 80 is also connected, it is confirmed that the fifth abnormal signal A5 is correct and the fuse blows out. When the contact point of the heater 540 is connected, and the contact point of the overheating detector 70 is connected, or when the contact point of the heater 540 is connected, a contact point of the electromagnetic contactor 520 is not connected, and a contact point of the solid state relay 530 is connected, it is determined that the heater 540 is damaged or burned out, and then it is confirmed that the fourth abnormal signal A4 is correct.

Further, similar to the first embodiment, the second embodiment may also have the warning unit 50 and the communication unit 60, to further start the warning unit 50 to generate a warning when the fourth abnormal signal A4 or the fifth abnormal signal A5 is received, or to further send the fourth abnormal signal A4 or the fifth abnormal signal A5 through the communication unit 60.

As described in the foregoing implementation, through disposing of the trip detector 20, the phase loss detector 30, and the current detector 40, as well as a logic circuit design of the control apparatus 10, an early warning notification may be issued in advance when a voltage and a current of the device are abnormal, and the operation of the heater 540 is interrupted, to avoid occurrence of temperature abnormalities during processes, thereby improving an overall yield and reducing a cost generated by scrapping products.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A temperature control and detection system, configured to be mounted on a heating device, wherein the heating device comprises a leakage circuit breaker, an electromagnetic contactor, a solid state relay, and a heater, and the temperature control and detection system comprises:
a control apparatus, electrically connected to the leakage circuit breaker, the electromagnetic contactor, the solid state relay, and the heater;
a trip detector, electrically connected to the control apparatus and the leakage circuit breaker, and when detecting that the leakage circuit breaker trips out, generating a first abnormal signal and sending the first abnormal signal to the control apparatus, to terminate operation of the heater;
a phase loss detector, electrically connected to the electromagnetic contactor, the solid state relay, and the control apparatus, and when detecting that a three-phase voltage is unbalanced, generating a second abnormal signal and sending the second abnormal signal to the control apparatus, to terminate the operation of the heater; and
a current detector, electrically connected to the solid state relay, the heater, and the control apparatus, and when detecting that a continuous current surge or a current is continuously lower than a threshold, generating a third abnormal signal and sending the third abnormal signal to the control apparatus, to terminate the operation of the heater.

2. The temperature control and detection system according to claim 1, wherein the control apparatus comprises a programmable logic control apparatus.

3. The temperature control and detection system according to claim 1, further comprising a warning unit, wherein when receiving the first abnormal signal, the second abnormal signal, or the third abnormal signal, the control apparatus sends an actuating signal to start the warning unit.

4. The temperature control and detection system according to claim 1, further comprising a communication unit, wherein when the control apparatus receives the first abnormal signal, the second abnormal signal, or the third abnormal signal, the control apparatus transmits the first abnormal signal, the control apparatus transmits the first abnormal signal, the second abnormal signal, or the third abnormal signal through the communication unit.

5. The temperature control and detection system according to claim 1, further comprising an overheating detector, connected to the heater and the control apparatus, and when detecting that a temperature of the heater is excessively high, generating a fourth abnormal signal and sending the fourth abnormal signal to the control apparatus to terminate the operation of the heater.

6. The temperature control and detection system according to claim 5, further comprising a warning unit, wherein when receiving the first abnormal signal, the second abnormal signal, the third abnormal signal, or the fourth abnormal signal, the control apparatus sends an actuating signal to start the warning unit.

7. The temperature control and detection system according to claim 5, further comprising a communication unit, wherein when the control apparatus receives the first abnormal signal, the second abnormal signal, the third abnormal signal, or the fourth abnormal signal, the control apparatus transmits the first abnormal signal, the second abnormal signal, the third abnormal signal, or the fourth abnormal signal through the communication unit.

8. The temperature control and detection system according to claim 5, further comprising a resistance detector, connected to the heater, and when detecting that a fuse of the heater blows out, generating a fifth abnormal signal and sending the fifth abnormal signal to the control apparatus to terminate the operation of the heater.

9. The temperature control and detection system according to claim 8, further comprising a warning unit, wherein when receiving the first abnormal signal, the second abnormal signal, the third abnormal signal, the fourth abnormal signal, or the fifth abnormal signal, the control apparatus sends an actuating signal to start the warning unit.

10. The temperature control and detection system according to claim 8, further comprising a communication unit, wherein when the control apparatus receives the first abnormal signal, the second abnormal signal, the third abnormal signal, the fourth abnormal signal, or the fifth abnormal signal, the control apparatus transmits the first abnormal signal, the second abnormal signal, the third abnormal signal, the fourth abnormal signal, or the fifth abnormal signal through the communication unit.
